(19) United States
(12) Patent Application Publication
(10) Pub. No.: US 2026/0150425 A1
(43) Pub. Date: May 28, 2026

(54) SEMICONDUCTOR STRUCTURE AND METHOD OF MANUFACTURING THEREOF

(71) Applicant: Taiwan Semiconductor Manufacturing Company, Ltd., Hsinchu (TW)

(72) Inventors: Yu-Fang Chiu, Taipei City (TW); Anhao Cheng, Taichung City (TW)

(73) Assignee: Taiwan Semiconductor Manufacturing Company, Ltd., Hsinchu (TW)

(21) Appl. No.: 18/962,306

(22) Filed: Nov. 27, 2024

(51) Int. Cl. H01L 27/146

(52) U.S. Cl. CPC H10F 39/809; H10F 39/018; H10F 39/811

(57) ABSTRACT

A semiconductor structure includes: a plurality of photosensitive pixels in a substrate; an interconnect structure over a first side of the substrate; a memory region including a plurality of memory cells formed in the interconnect structure, wherein the interconnect structure is configured to couple photosensitive pixels to the plurality of memory cells; and an Image Signal Processor (ISP) coupled to the plurality of memory cells via the interconnect structure, wherein the ISP is configured to provide a neuromorphic computing capability.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts a schematic cross-sectional view of an example portion of an example CIS system with memory cells and that provides neuromorphic computing capability, according to some embodiments.

FIG. 2A depicts a plan or layout view illustrating an example CMOS image sensor, according to some embodiments.

FIG. 2B illustrates a cross sectional view of the photosensitive detection area of the CMOS image sensor along cutline L-L′ of FIG. 2A in the photosensitive detection area, in accordance with some embodiments.

FIG. 2C is a schematic diagram depicting a plurality of pixel transistors, according to some embodiments.

FIG. 3 is a schematic cross-sectional view of a portion of an example memory cell region, according to some embodiments.

FIG. 4A depicts an example vertical serial memory array, according to some embodiments.

FIG. 4B depicts an example horizontal serial memory array, according to some embodiments.

FIG. 4C depicts an example vertical and horizontal serial memory array, according to some embodiments.

FIG. 4D depicts an example horizontal serial memory array, according to some embodiments.

FIG. 5A depicts a schematic cross-sectional view of an example portion of another example CIS system that provides memory cells and neuromorphic computing capability, according to some embodiments.

FIG. 5B depicts a schematic cross-sectional view of an example portion of another example CIS system that provides memory cells and neuromorphic computing capability, according to some embodiments.

FIGS. 6-8 depict schematic cross-sectional diagrams illustrating example substrates with a memory cell transistor(s) on the substrate, a first interconnect structure with a first memory array above the substrate, and a second interconnect structure with a second memory array below the substrate, and according to some embodiments.

FIG. 9 depicts a schematic diagram illustrating an example artificial perception application of a CIS system that provides memory cells and neuromorphic computing capability, according to some embodiments.

FIG. 10 depicts a block diagram illustrating an example application of a CIS system that provides memory cells and neuromorphic computing capability, according to some embodiments.

FIG. 11 depicts s a flowchart of an example method for fabricating a CIS system with neuromorphic computing capability, according to some embodiments.

FIGS. 12-19 depict schematic cross-sectional diagrams illustrating example substrates with a memory cell transistor(s) on the substrate, a first interconnect structure with a first memory array above the substrate, and a second interconnect structure with a second memory array below the substrate, and according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers, and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90°that is less than or equal to ±10°, such as less than or equal to ±5°less than or equal to ±4°, less than or equal to ±3°, less than or equal to ±2°, less than or equal to ±1°, less than or equal to ±0.5°, less than or equal to ±0.1°, or less than or equal to ±0.05°.

Semiconductor image sensors are used to sense incoming visible or non-visible radiation, such as visible light, infrared light, etc. Complementary metal-oxide-semiconductor (CMOS) image sensors (CIS) and charge-coupled device (CCD) sensors are used in various applications, such as digital still cameras, mobile phones, tablets, goggles, etc. These image sensors utilize an array of pixels that absorb (e.g., sense) the incoming radiation and convert it into electrical signals. An example of an image sensor is a backside illuminated (BSI) image sensor, which detects radiation from a “backside” of a substrate of the BSI image sensor.

A backside illumination (BSI) image sensor is a type of CIS device. A BSI image sensor includes a pixel region with an array of pixels or radiation-sensing regions formed on a substrate (e.g., a semiconductor substrate). The terms “radiation-sensing regions” and “pixels” may be used interchangeably throughout this disclosure. The pixels are configured to convert photons from the incident radiation to an electrical signal. The electrical signal is subsequently distributed to processing components attached to the BSI image sensor. For this reason, the pixel region overlies an interconnect structure in a multilevel metallization layer configured to distribute the electrical signal generated within the pixels to appropriate processing components. The multilevel metallization layer is formed on a first surface of the substrate referred to as the “front side” surface of the substrate. The pixel region is formed on a second surface of the substrate that is opposite to the front side surface of the substrate. This second surface of the substrate is referred to herein as the “backside” surface of the substrate. The pixel region includes a grid structure that provide optical isolation between adjacent pixels. Further, the pixel region includes color filtering layers. The material of color filtering layers can be selected such that light with a desired wavelength passes through the color filtering layers, while light with other wavelengths is absorbed by the color filtering layers.

Described herein are systems, methods, techniques, and articles that can provide high speed image computing using CIS circuits. The described systems, methods, techniques, and articles enable high speed image computing using CIS circuits that provide neuromorphic computing capabilities. The described systems, methods, techniques, and articles can provide for neuromorphic computing at a wafer frontside, a wafer backside, or at both of a wafer frontside and backside. The described systems, methods, techniques, and articles can provide for neuromorphic computing by integrating horizontal and/or vertical serial memory cells into CIS circuits. The described systems, methods, techniques, and articles can provide CIS circuits with a plurality of memory cells that can be programmed with quantized weights in image sensing neurons. The described systems, methods, techniques, and articles can provide a CIS circuit with horizontal and/or vertical serial MRAM and/or RRAM memory cells and neuromorphic computing that can provide high-speed image processing and highly efficient energy consumption.

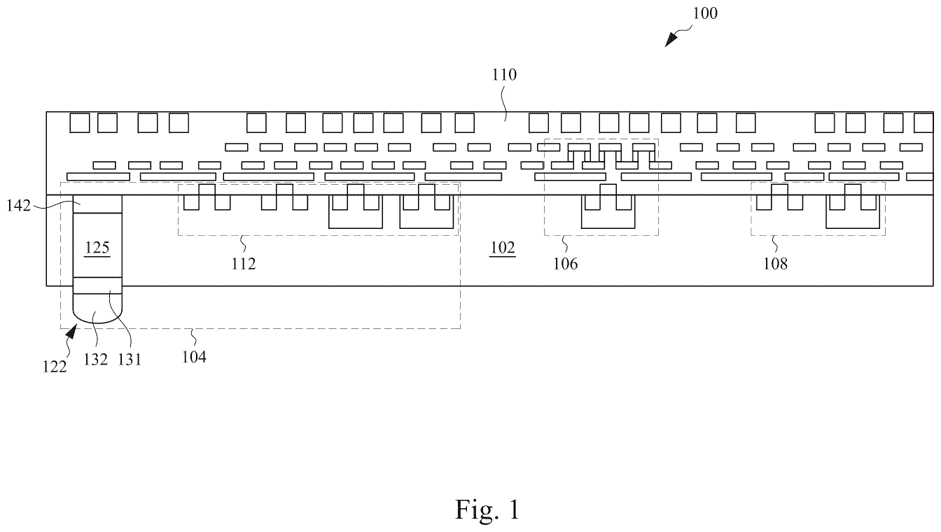

FIG. 1 depicts a schematic cross-sectional view of a portion of an example CIS system 100 with memory cells and that provides neuromorphic computing capability, according to some embodiments. The example CIS system 100 includes a semiconductor substrate 102 with a photosensitive pixel region 104 comprising a plurality of photosensitive pixels, a memory cell region 106, and an Image Signal Processor region (ISP region 108) disposed on the semiconductor substrate 102. The example CIS system 100 also includes an interconnect structure 110 of a multi-level metallization layer, which is embedded in an ILD layer of the multi-level metallization layer, disposed over the semiconductor substrate 102 that interconnects components (e.g., transistors) of the photosensitive pixel region 104, memory cell region 106, and ISP region 108 to form a CIS system with neuromorphic computing capability.

The interconnect structure 110 provides routing and electrical connections between device elements formed in and/or over the substrate. The interconnect structure 110 may include one or more conductive features, which in this example include metal lines and/or VIAs formed therein in multi-level metallization layer. The conductive features may be electrically connected to active and/or passive devices of the substrate by contacts (not shown in the figures). In some embodiments, the interconnect structure may be formed using a single and/or a dual damascene process, a VIA-first process, or a metal-first process.

The substrate 102 may be a semiconductor substrate, such as a bulk semiconductor, a semiconductor-on-insulator (SOI) substrate, a semiconductor wafer, or the like, which may be doped (e.g., with a p-type or an n-type dopant) or undoped. Other substrates, such as a multi-layered or gradient substrate may also be used. In some embodiments, the semiconductor material of the substrate may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

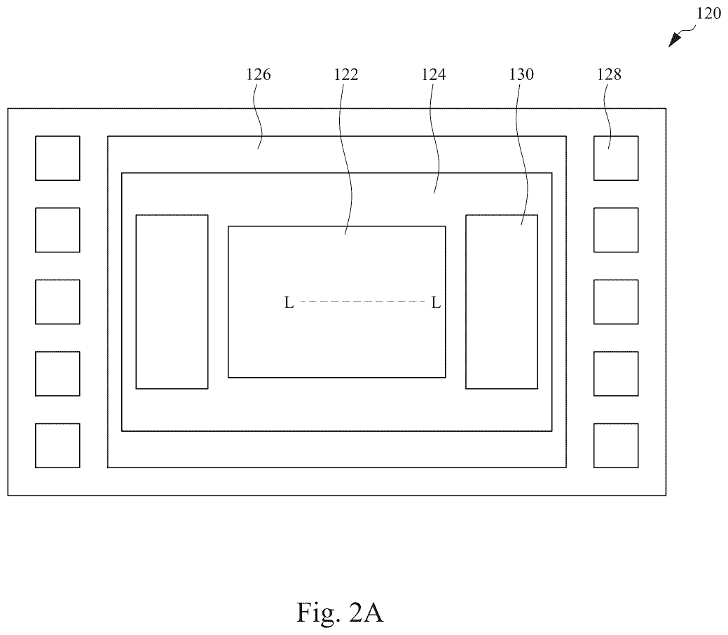

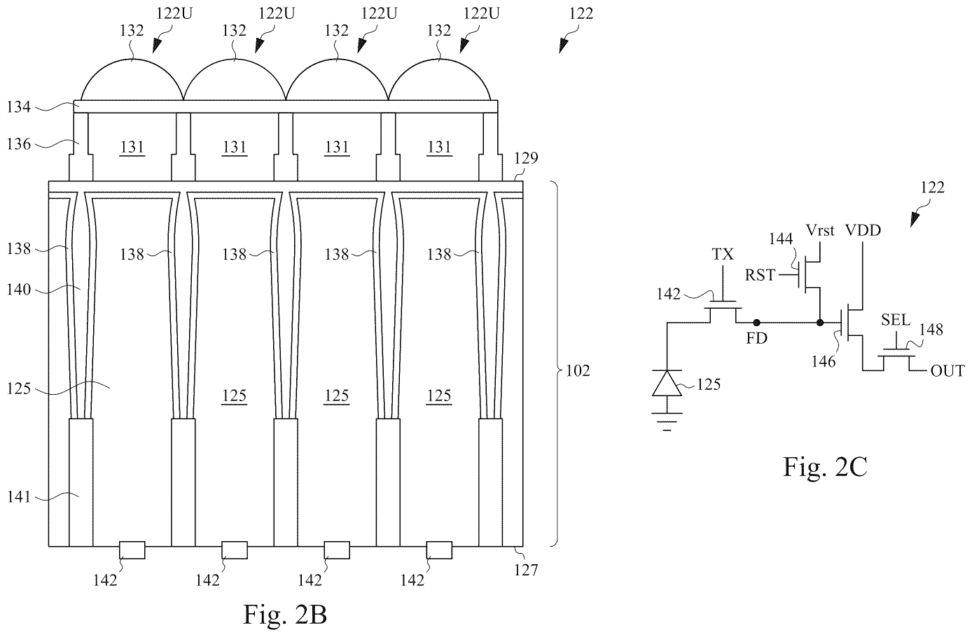

The photosensitive pixel region 104 illustrates one of a plurality of photosensitive pixel regions in the CIS system 100, is part of a larger CMOS image sensor, and includes a plurality of pixel transistors 112 and a photosensitive detection area 122. FIG. 2A depicts a plan or layout view illustrating an example CMOS image sensor 120 according to some embodiments. The example CMOS image sensor 120 include a photosensitive detection area 122 in which a plurality of unit photosensitive detection areas are arranged in a matrix, and an optical isolation region 124 surrounding the photosensitive detection area 122. Further, the optical isolation region 124 is surrounded by a physical isolation area 126. In some embodiments, the CMOS image sensor 120 includes a plurality of pad electrodes 128 for wiring to outside circuitry. The example CMOS image sensor 120 further includes one or more black level calibration (BLC) area 130 which blocks incident light and provide a reference dark voltage current.

FIG. 2B illustrates a cross sectional view of the photosensitive detection area 122 of the CMOS image sensor 120 along cutline L-L′ of FIG. 2A in the photosensitive detection area 122, in accordance with some embodiments. The photosensitive detection area 122 includes a plurality of unit photosensitive detection areas 122U, each of which includes a photodiode layer 125 formed in a semiconductor substrate 102 having a first side 127 and an opposing second side 129, a color filter 131 disposed over the second side 129 and substantially aligning with the photodiode layer 125, and a micro-lens 132 disposed over and aligning with the color filter 131. In some embodiments, a liner dielectric layer 134 is disposed between the color filter 131 and the micro-lens 132. The CMOS image sensor 120 also includes a first isolation structure 136 to laterally separate adjacent color filters 131. The example CMOS image sensor 120 includes a second isolation structure 138, which is a deep trench isolation structure filled with one or more dielectric materials 140, disposed in the semiconductor substrate 102 to laterally separate adjacent photodiode layers 125. In addition, the CMOS image sensor 120 includes a pass transistor 142 coupled to the photodiode layer 125 disposed on the first side 127 of the semiconductor substrate 102. In some embodiments, a third isolation structure 141, which is a doped region implanted with, for example, boron, is disposed between and aligning with the second isolation structure 138 and the first side 127, and functions as an electrical isolation structure. In some embodiments, each unit photosensitive detection area 122U has a square or a rectangular shape in plan view and is surrounded by the first isolation structure 136, second isolation structure 138, and third isolation structure 141.

The unit photosensitive detection area 122U also include a floating diffusion (FD) region coupled to a plurality of pixel transistors (not shown). FIG. 2C is a schematic diagram depicting a plurality of pixel transistors 112, according to some embodiments. The plurality of pixel transistors 112 includes the pass transistor 142, a reset transistor 144, a source follower transistor 146, and a select transistor 148.

During operation of the photosensitive pixel region 104, charge is accumulated in response to incident radiation. The pass transistor 142 selectively transfers accumulated charge at the photodiode layer 125 of the photosensitive detection area 122 to the floating diffusion FD region. The pass transistor 142 is gated by a pass signal TX and includes a pair of first source/drain regions. One of the first source/drain regions is formed by the floating diffusion FD region, and the other of the first source/drain regions is formed by a doped region of the photosensitive pixel region 104. The source/drain regions may refer to the source or drain individually or collectively, depending on the context. The reset transistor 144 is gated by a reset signal RST and is electrically coupled from the floating diffusion FD region to a terminal to which a reset voltage Vᵣₛₜ is applied. The reset transistor 144 is configured to reset the floating diffusion FD region to a reset voltage Vᵣₛₜ by electrically coupling the floating diffusion node FD to the reset voltage Vᵣₛₜ. The source follower transistor 146 is gated by the charge at the floating diffusion FD region and the select transistor 148 is gated by a select signal SEL. Further, the source follower transistor 146 and the select transistor 148 are electrically coupled in series from a terminal to which the power supply voltage VDD is applied to the output terminal OUT. The source follower transistor 146 is configured to buffer and amplify the voltage at the floating diffusion FD region. The select transistor 148 is configured to selectively pass the buffered and amplified voltage from the source follower transistor 146 to the output terminal OUT.

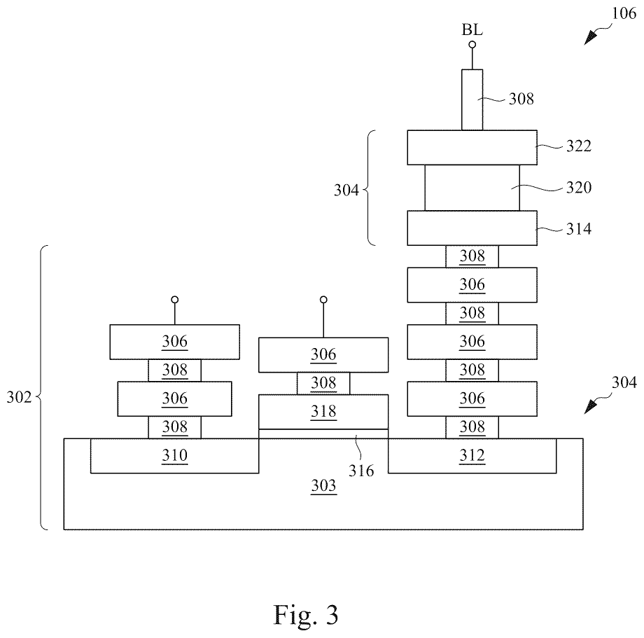

FIG. 3 is a schematic cross-sectional view of a portion of an example memory cell region 106. The example memory cell region 106 is included in an interconnect structure 302 disposed over a substrate 303 and a memory cell 304 disposed within the interconnect structure 302. The interconnect structure 302 comprises a plurality of stacked interconnect metal layers that include interconnect metal lines 306 and VIAs 308 disposed within an ILD layer. The example memory cell region 106 further includes a memory cell transistor formed in the substrate 303. The memory cell transistor includes a first source/drain region 310 coupled via interconnect metal lines 306 and VIAs 308 to a select line SL and a second source/drain region 312 coupled via interconnect metal lines 306 and VIAs 308 to a bottom electrode 314 of the memory cell 304. The memory cell transistor further includes a gate dielectric layer 316 formed over the substrate 303 and a metal gate layer 318 formed over the gate dielectric layer 316. The metal gate layer 318 is coupled via interconnect metal lines 306 and VIAs 308 to a word line WL.

Conductive material for the metal lines and/or VIAs may be formed from conductive material, such as copper (Cu), aluminum (Al), tungsten (W), nickel, cobalt, silver, combinations thereof, or other applicable materials, and may be formed using an electro-chemical plating process, chemical vapor deposition (CVD), atomic layer deposition (ALD), physical vapor deposition (PVD), the like, or a combination thereof. After formation of the conductive material, excess conductive material may be removed using, for example, a planarization process such as chemical mechanical polishing (CMP). The interconnect structure may include one or more metal layers and one or more intermetal dielectric (IMD) layers.

The memory cell 304 may comprise a bottom electrode 314, a data storage structure 320 arranged over the bottom electrode 314, and a top electrode 322 arranged over the data storage structure 320. The top electrode 322 may be coupled to a bit line BL via interconnect metal lines 306 and VIAs 308. In some embodiments, the bottom electrode 314 and the top electrode 322 may comprise titanium (Ti), tantalum (Ta), Hafnium (Hf), tantalum nitride (TaN), titanium nitride (TiN), ruthenium (Ru), Platinum (Pt), Gold (Au), Silver (Ag), Copper (Cu), Zirconium (Zr), Aluminum (Al), Lead (Pb), Tungsten (W), Iridium (Ir), Cobalt (Co), Zinc (Zn), Molybdenum (Mo), Gallium (Ga), Germanium (Ge), Palladium (Pd), Indium tin oxide (ITO), Indium zinc oxide (IZO) or other suitable material. The bottom electrode and the top electrode may be formed from a single film, composite film, or dopant film.

In some embodiments, the data storage structure 320 is a magnetic tunnel junction (MTJ) or a spin-valve. In such cases, the memory cell 304 is referred as a magnetic memory cell, and the memory cell region 106 that is made of an array of such memory cells 304 is referred as a magnetoresistive random access memory (MRAM) device.

In some alternate embodiments, the data storage structure 320 comprises a material having a variable resistance configured to undergo a reversible phase change between a high resistance state and a low resistance. In various embodiments, a high-k dielectric material such as Titanium oxide (TiO), tantalum oxide (TaO), Hafnium (HfO), titanium oxy nitride (TiON), tantalum oxy nitride (TaON), ruthenium (RuO), silicon oxide (SiO), silver oxide (AgO), copper oxide (CuO), Zirconium oxide (ZrO), tungsten oxide (WO), Iridium oxide (IrO), cobalt oxide (CoO), zinc oxid (ZnO), Molybdenum oxide (MoO), Palladium oxide (PdO), Indium-oxygen (InO), Gallium oxide (GaO), lead oxide (PbO), aluminum oxide (AlO), stannous oxide (SnO), Germanium oxide (GeO), Boron monoxide (BO), BNO, and other suitable compounds may be used. In various embodiments, other semiconductor material, such as nickel oxide (NiO), strontium titanate (Sr(Zr)TiO₃), hafnium dioxide (HfO₂), zirconium dioxide (ZrO₂), aluminum oxide (Al₂O₃), tantalum pentoxide (Ta₂O₅), hafnium aluminum oxide (HfAlO), hafnium zirconium oxide (HfZrO), or the like may be used.

In such cases, the memory cell 304 is referred as a resistive memory cell, and the memory cell region 106 made of an array of such memory cells 304 is referred as a resistive random access memory (ReRAM or RRAM) device. Depending on voltages applied to the electrodes, the data storage structure 320 will undergo a reversible change between a high resistance state associated with a first data state (e.g., a ‘0’ or ‘RESET’) and a low resistance state associated with a second data state (e.g., a ‘1’ or ‘SET’). Once a resistance state is set, an RRAM cell will retain the resistive state until another voltage is applied to induce a RESET operation (resulting in a high resistance state) or a SET operation (resulting in a low resistance state).

In some further embodiments, the data storage structure 320 comprises a phase-change material, such as Ge₂Sb₂Te₅, and the memory cell region 106 made of an array of such data storage structures 320 is referred as a PCRAM device. Other suitable types of structures for the data storage structure 320 and/or other memory-cell types for the memory cell 304 may be used.

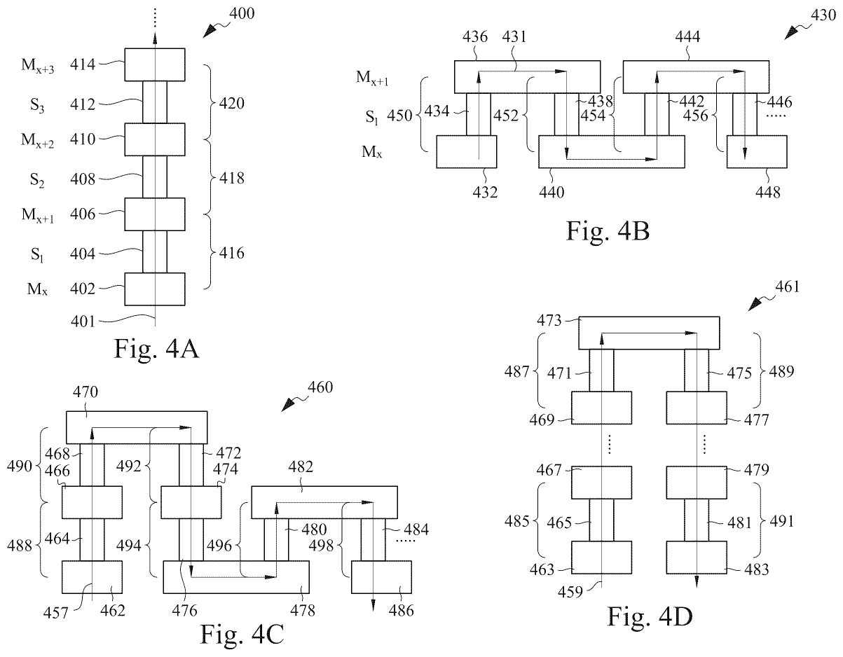

FIGS. 4A, 4B, 4C, and 4D are schematic cross-sectional views of different example arrangements of a memory cell region 106. FIG. 4A depicts an example vertical serial memory array 400. In the example vertical serial memory array 400, data flows serially in a direction 401 from one memory cell to another. The example vertical serial memory array 400 includes a plurality of electrode layers disposed in different metal layers and a plurality of data storage structures disposed between two electrode layers. In this example, illustrated are a first electrode layer 402 at a first metal layer Mₓ, a first data storage structure 404 at a first data storage layer S₁, a second electrode layer 406 at a second metal layer Mₓ₊₁, a second data storage structure 408 at a second data storage layer S₂, a third electrode layer 410 at a third metal layer Mₓ₊₂, a third data storage structure 412 at a third data storage layer S₃, and a fourth electrode layer 414 at a fourth metal layer Mₓ₊₃.

The example vertical serial memory array 400 includes a plurality (3 in this example) of serial memory cells that are configured to pass content in series from one memory cell in one interconnect level to another memory cell in a higher or lower interconnect level (e.g., the first data storage structure 404 is in a first interconnect level, the second data storage structure 408 is in a second interconnect level that is higher than the first interconnect level, and the third data storage structure 412 is in a third interconnect level that is higher than the second interconnect level). The plurality of serial memory cells include a first memory cell 416, a second memory cell 418, and a third memory cell 420. The first memory cell 416 is configured to pass content in series to the second memory cell 418, and the second memory cell 418 is configured to pass content in series to the third memory cell 420.

The first memory cell 416 is formed with the first electrode layer 402 as a bottom electrode, the first data storage structure 404 as the data storage structure for the memory cell, and the second electrode layer 406 as the top electrode for the memory cell. A second memory cell 418 is formed with the second electrode layer 406 as a bottom electrode, the second data storage structure 408 as the data storage structure, and the third electrode layer 410 as the top electrode for the memory cell. A third memory cell 420 is formed with the third electrode layer 410 as a bottom electrode, the third data storage structure 412 as the data storage structure, and the fourth electrode layer 414 as the top electrode for the memory cell.

FIG. 4B depicts an example horizontal serial memory array 430. In the example horizontal serial memory array 430, data flows serial in a direction 431 from one memory cell to another. The example horizontal serial memory array 430 includes a plurality of electrodes and a plurality of data storage structures disposed between two electrodes. In this example, illustrated are a first electrode 432 at a first metal layer Mₓ, a first data storage structure 434 at a first data storage layer S₁, a second electrode 436 at a second metal layer Mₓ₊₁, a second data storage structure 438 at the first data storage layer S₁, a third electrode 440 at the first metal layer Mₓ, a third data storage structure 442 at a first data storage layer S₁, a fourth electrode 444 at the first metal layer Mₓ₊₁, a fourth data storage structure 446 at the first data storage layer S₁, and a fifth electrode 448 at the first metal layer Mₓ.

The example horizontal serial memory array 430 includes a plurality (4 in this example) of serial memory cells that are configured to pass content in series from one memory cell in one interconnect level to another memory cell in the same interconnect level (e.g., the first data storage structure 434, the second data storage structure 438, the third data storage structure 442, and the fourth data storage structure 446 are in the same interconnect level). The plurality of serial memory cells include a first memory cell 450, a second memory cell 452, a third memory cell 454, and a fourth memory cell 456. The first memory cell 450 is configured to pass content in series to the second memory cell 452. The second memory cell 452 is configured to pass content in series to the third memory cell 454. The third memory cell 454 is configured to pass content in series to the fourth memory cell 456.

The first memory cell 450 is formed with the first electrode 432 as a bottom electrode, the first data storage structure 434 as the data storage structure for the memory cell, and the second electrode 436 as the top electrode for the memory cell. The second memory cell 452 is formed with the second electrode 436 as a bottom electrode, the second data storage structure 438 as the data storage structure, and the third electrode 440 as the top electrode for the memory cell. The third memory cell 454 is formed with the third electrode 440 as a bottom electrode, the third data storage structure 442 as the data storage structure, and the fourth electrode 444 as the top electrode for the memory cell. The fourth memory cell 456 is formed with the fourth electrode 444 as a bottom electrode, the fourth data storage structure 446 as the data storage structure, and the fifth electrode 448 as the top electrode for the memory cell.

FIG. 4C depicts an example vertical and horizontal serial memory array 460. In the example vertical and horizontal serial memory array 460, data flows serial in a direction 457 from one memory cell to another. The example vertical and horizontal serial memory array 460 includes a plurality of electrodes and a plurality of data storage structures disposed between two electrodes. In this example, illustrated are a first electrode 462 at a first metal layer Mₓ, a first data storage structure 464 at a first data storage layer S₁, a second electrode 466 at a second metal layer Mₓ₊₁, a second data storage structure 468 at a second data storage layer S₂, a third electrode 470 at a third metal layer Mₓ₊₂, a third data storage structure 472 at the second data storage layer S₂, a fourth electrode 474 at the second metal layer Mₓ₊₁, a fourth data storage structure 476 at the first data storage layer S₁, a fifth electrode 478 at the first metal layer Mₓ, a fifth data storage structure 480 at the first data storage layer S₁, a sixth electrode 482 at the second metal layer Mₓ₊₁, a sixth data storage structure 484 at the first data storage layer S₁, and a seventh electrode 486 at the first metal layer metal layer Mₓ.

The example vertical and horizontal serial memory array 460 includes a plurality (6 in this example) of serial memory cells that are configured to pass content in series from one memory cell to another memory cell. The plurality of serial memory cells include a first memory cell 488, a second memory cell 490, a third memory cell 492, a fourth memory cell 494, a fifth memory cell 496, and a sixth memory cell 498. The first memory cell 488 is configured to pass content in series to the second memory cell 490. The second memory cell 490 is configured to pass content in series to the third memory cell 492. The third memory cell 492 is configured to pass content in series to the fourth memory cell 494. The fourth memory cell 494 is configured to pass content in series to the fifth memory cell 496. The fifth memory cell 496 is configured to pass content in series to the sixth memory cell 498.

The first memory cell 488 is formed with the first electrode 462 as a bottom electrode, the first data storage structure 464 as the data storage structure for the memory cell, and the second electrode 466 as the top electrode for the memory cell. The second memory cell 490 is formed with the second electrode 466 as a bottom electrode, the second data storage structure 468 as the data storage structure, and the third electrode 470 as the top electrode for the memory cell. The third memory cell 492 is formed with the third electrode 470 as a bottom electrode, the third data storage structure 472 as the data storage structure, and the fourth electrode 474 as the top electrode for the memory cell. The fourth memory cell 494 is formed with the fourth electrode 474 as a bottom electrode, the fourth data storage structure 476 as the data storage structure, and the fifth electrode 478 as the top electrode for the memory cell. The fifth memory cell 496 is formed with the fifth electrode 478 as a bottom electrode, the fifth data storage structure 480 as the data storage structure, and the sixth electrode 482 as the top electrode for the memory cell. The sixth memory cell 498 is formed with the sixth electrode 482 as a bottom electrode, the sixth data storage structure 484 as the data storage structure, and the seventh electrode 486 as the top electrode for the memory cell.

FIG. 4D depicts another example vertical and horizontal serial memory array 461. In the example vertical and horizontal serial memory array 461, data flows serial in a direction 459 from one memory cell to another. The example vertical and horizontal serial memory array 461 includes a plurality of electrodes and a plurality of data storage structures disposed between two electrodes. In this example, illustrated are a first electrode 463 at a first metal layer Mₓ, a first data storage structure 465 at a first data storage layer S₁, a second electrode 467 at a second metal layer Mₓ₊₁, a third electrode 469 at a third metal layer, a second data storage structure 471 at a second data storage layer, a fourth electrode 473 at a fourth metal layer, a third data storage structure 475 at the second data storage layer, a fifth electrode 477 at the third metal layer, a sixth electrode 479 at the second metal layer Mₓ₊₁, a fourth data storage structure 481 at the first data storage layer S₁, and a seventh electrode 483 at the first metal layer metal layer Mₓ.

The example vertical and horizontal serial memory array 461 includes a plurality (4 in this example) of serial memory cells that are configured to pass content in series from one memory cell to another memory cell. The plurality of serial memory cells include a first memory cell 485, a second memory cell 487, a third memory cell 489, and a fourth memory cell 491. The first memory cell 485 is configured to pass content in series to intervening memory cell(s) (not shown) and eventually to the second memory cell 487. The second memory cell 487 is configured to pass content in series to the third memory cell 489. The third memory cell 489 is configured to pass content in series to intervening memory cell(s) (not shown) and eventually to the fourth memory cell 491.

The first memory cell 485 is formed with the first electrode 463 as a bottom electrode, the first data storage structure 465 as the data storage structure for the memory cell, and the second electrode 467 as the top electrode for the memory cell. The second memory cell 487 is formed with the third electrode 469 as a bottom electrode, the second data storage structure 471 as the data storage structure, and the fourth electrode 473 as the top electrode for the memory cell. The third memory cell 489 is formed with the fourth electrode 473 as a bottom electrode, the third data storage structure 475 as the data storage structure, and the fifth electrode 477 as the top electrode for the memory cell. The fourth memory cell 491 is formed with the sixth electrode 479 as a bottom electrode, the fourth data storage structure 481 as the data storage structure, and the seventh electrode 483 as the top electrode for the memory cell.

Referring back to FIG. 1, The ISP region 108 may comprise an ISP, which may transmit an image signal captured by the CMOS image sensor 120 to a display device such as a digital TV. The ISP may also remove noise from the image signal input thereto, deinterlace the image signal when the image signal is an interlaced image signal or scale the image signal. Together with the CMOS image sensor 120, the ISP region 108 defines the image quality and the speed performance of a camera subsystem, for example, in a mobile handset. The ISP region 108 may comprise a plurality of multiprocessors that works with the serial memory arrays in the memory cell region 106. The ISP region 108 along with the memory cell region 106 can provide neuromorphic computing capability for a CIS system.

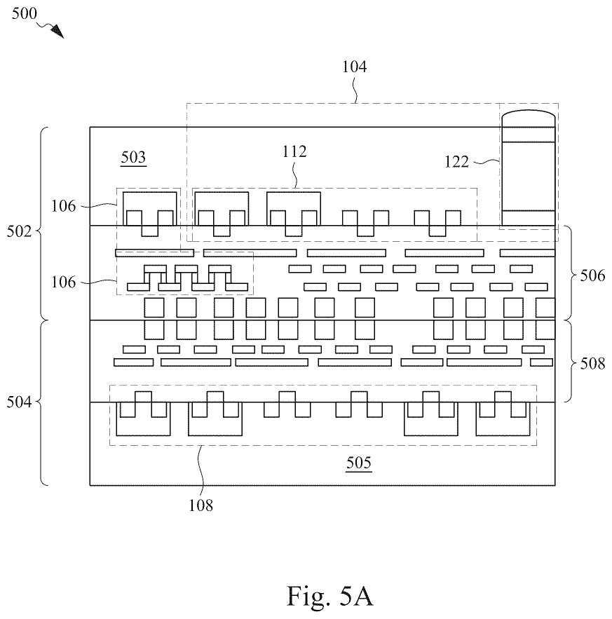

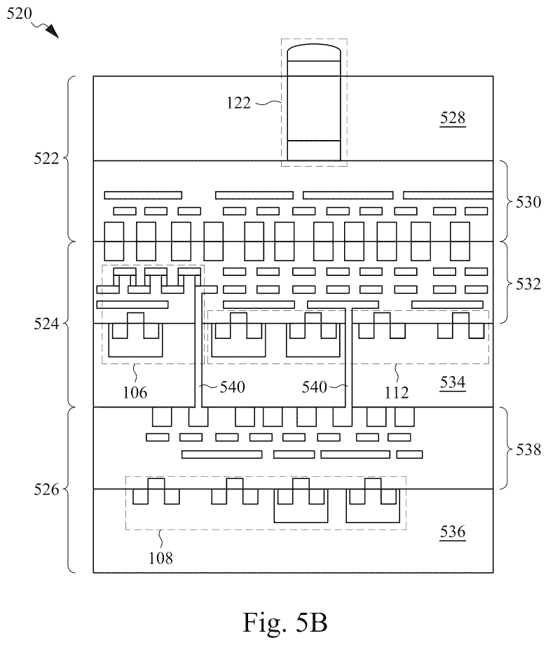

FIG. 5A depicts a schematic cross-sectional view of an example portion of another example CIS system 500 that provides memory cells and neuromorphic computing capability, according to some embodiments. The example CIS system 500 includes a first semiconductor wafer 502 joined to a second semiconductor wafer 504. The first semiconductor wafer 502 and the second semiconductor wafer 504 are front-side to front-side bonded. The first semiconductor wafer 502 and the second semiconductor wafer 504 may be joined by various wafer bonding processes having various parameters. In some examples, the wafer bonding processes may include direct wafer bonding (fusion bonding), anodic bonding, thermocompression bonding, adhesive bonding, eutectic bonding, and plasma-assisted bonding.

The first semiconductor wafer 502 includes a substrate 503 with a photosensitive pixel region 104, a memory cell region 106, and a first interconnect structure 506 disposed over the substrate 503. The first interconnect structure 506 interconnects components (e.g., transistors) of the photosensitive pixel region 104 and the memory cell region 106.

The second semiconductor wafer 504 includes a substrate 505 with an ISP region 108 disposed on the semiconductor substrate 102 and a second interconnect structure 508 disposed over the substrate 505. The second interconnect structure 508 interconnects components (e.g., transistors) of the ISP region 108 with components of the photosensitive pixel region 104 and the memory cell region 106 via the first interconnect structure 506.

FIG. 5B depicts a schematic cross-sectional view of an example portion of another example CIS system 520 that provides memory cells and neuromorphic computing capability, according to some embodiments. The example CIS system 520 includes a first semiconductor wafer 522 joined to a second semiconductor wafer 524 and a third semiconductor wafer 526 joined to the second semiconductor wafer 524. The first semiconductor wafer 522 and the second semiconductor wafer 524 are front-side to front-side bonded, and the third semiconductor wafer 526 and the second semiconductor wafer 524 are front-side to back-side bonded. The first semiconductor wafer 522 and the second semiconductor wafer 524 may be joined by various wafer bonding processes having various parameters. Likewise, the second semiconductor wafer 524 and the third semiconductor wafer 526 may be joined by various wafer bonding processes having various parameters. In some examples, the wafer bonding processes may include direct wafer bonding (fusion bonding), anodic bonding, thermocompression bonding, adhesive bonding, eutectic bonding, and plasma-assisted bonding.

The first semiconductor wafer 522 includes a substrate 528 with a photosensitive detection area 122 and a first interconnect structure 530 disposed over the substrate 528. The first interconnect structure 530 interconnects the photosensitive detection area 122 with a second interconnect structure 532.

The second semiconductor wafer 524 includes a substrate 534 with a memory cell region 106 and a plurality of pixel transistors 112 disposed on the substrate 534 and the second interconnect structure 532 disposed over the substrate 534. The second interconnect structure 532 interconnects components (e.g., transistors) of the memory cell region 106 with components of the plurality of pixel transistors 112 and interconnects the photosensitive detection area 122 with the memory cell region 106 and the plurality of photosensitive detection area 122 via the first interconnect structure 530. One or more Through Silicon VIAs (TSV(s) 540) penetrate through the substrate 534 of the second semiconductor wafer 524 to connect the second interconnect structure 532 to a third interconnect structure 538 of the third semiconductor wafer 526.

The third semiconductor wafer 526 includes a substrate 536 with an ISP region 108 disposed on the substrate 536 and the third interconnect structure 538 disposed over the substrate 536. The third interconnect structure 538 interconnects components (e.g., transistors) of the ISP region 108. The third interconnect structure 538 also interconnects components of the ISP region 108 with components of the memory cell region 106 and the photosensitive detection area 122 through TSV(s) 540 and the second interconnect structure 532.

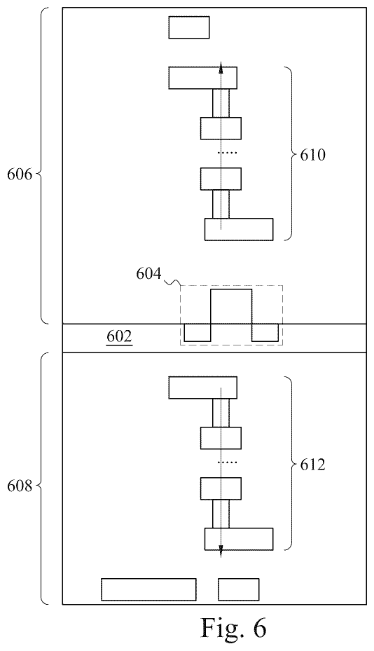

In various embodiments, a memory cell region may include memory cells in an interconnect structure above a substrate containing memory cell transistors and in an interconnect structure below the substrate containing the memory cell transistors. FIGS. 6, 7, and 8 are schematic cross-sectional diagrams depicting various memory cell arrangements in which a memory cell region includes memory cells in an interconnect structure above a substrate containing memory cell transistors and in an interconnect structure below the substrate containing the memory cell transistors.

FIG. 6 depicts a substrate 602 with memory cell transistor(s) 604 on the substrate, a first interconnect structure 606 above the substrate and a second interconnect structure 608 below the substrate. The first interconnect structure 606 includes a first memory array 610, and the second interconnect structure 608 includes a second memory array 612. The memory cell transistor(s) 604 is configured to provide data to each of the first memory array 610 and the second memory array 612. In this example, each of the first memory array 610 and the second memory array 612 comprises a vertical serial memory array.

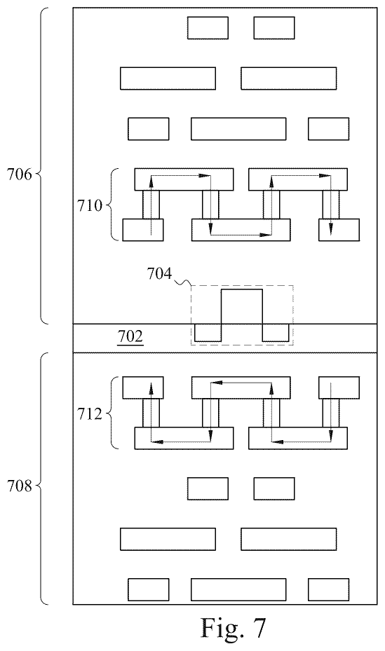

FIG. 7 depicts a substrate 702 with memory cell transistor(s) 704 on the substrate, a first interconnect structure 706 above the substrate and a second interconnect structure 708 below the substrate. The first interconnect structure 706 includes a first memory array 710, and the second interconnect structure 708 includes a second memory array 712. The memory cell transistor(s) 704 is configured to provide data to each of the first memory array 710 and the second memory array 712. In this example, each of the first memory array 710 and the second memory array 712 comprises a horizontal serial memory array.

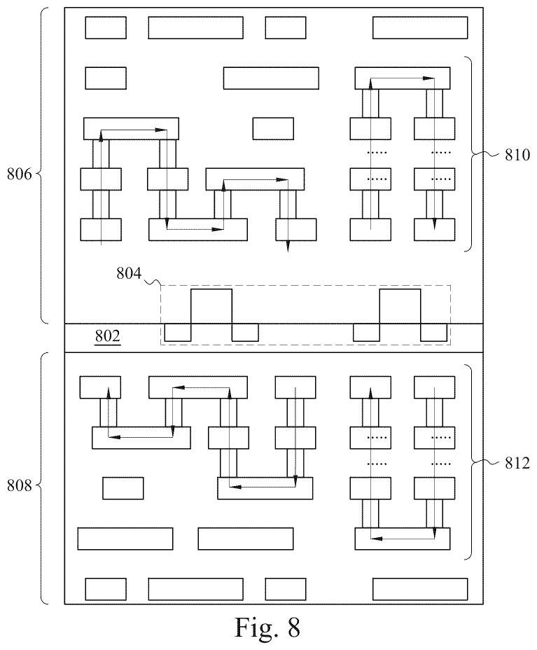

FIG. 8 depicts a substrate 802 with memory cell transistors 804 on the substrate, a first interconnect structure 806 above the substrate and a second interconnect structure 808 below the substrate. The first interconnect structure 806 includes a first memory array 810, and the second interconnect structure 808 includes a second memory array 812. The memory cell transistors 804 are configured to provide data to the first memory array 810 and the second memory array 812. In this example, each of the first memory array 810 and the second memory array 812 comprises a vertical and horizontal serial memory array.

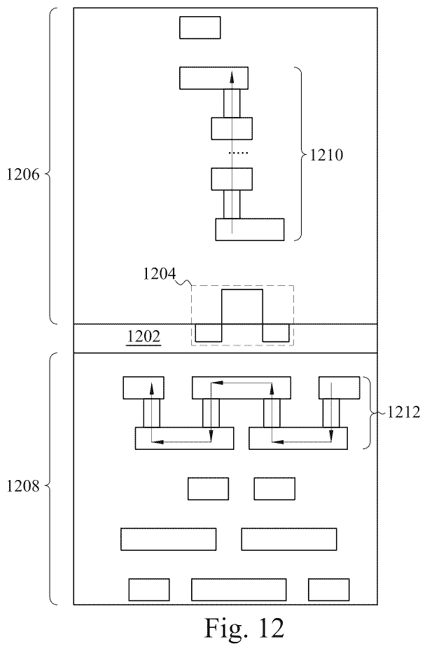

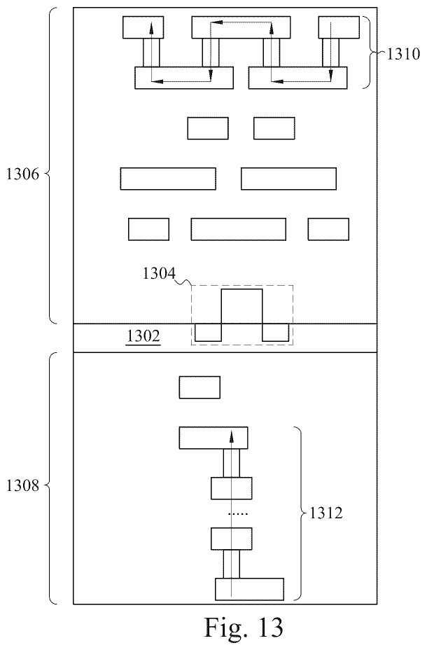

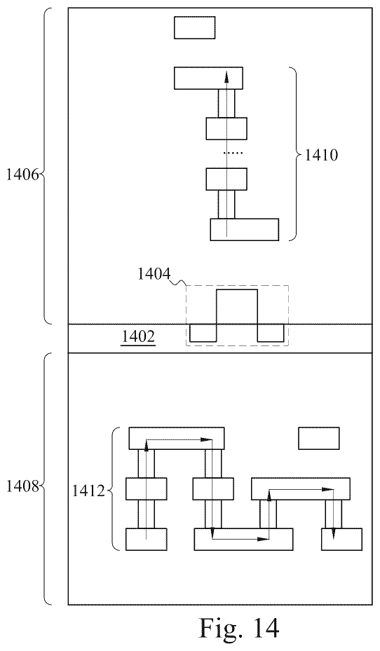

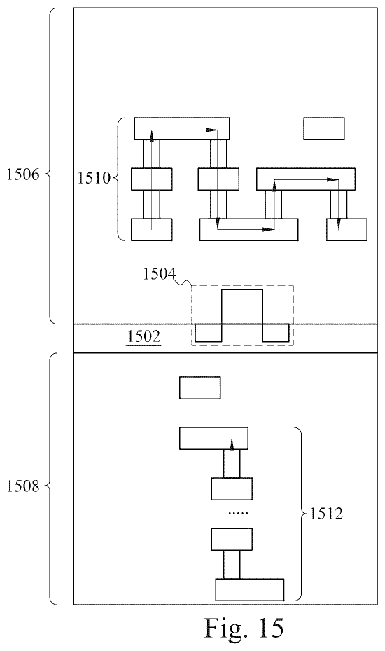

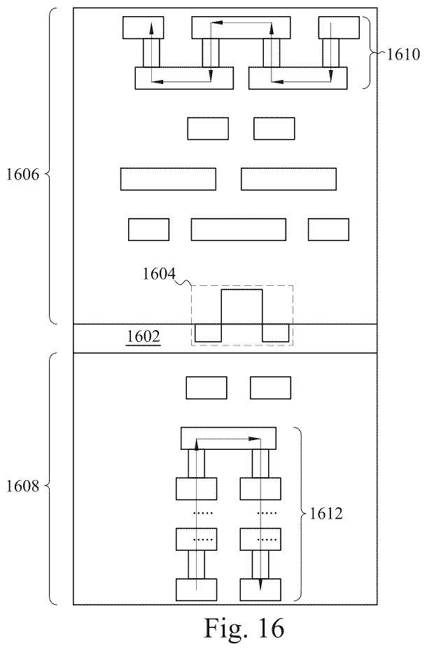

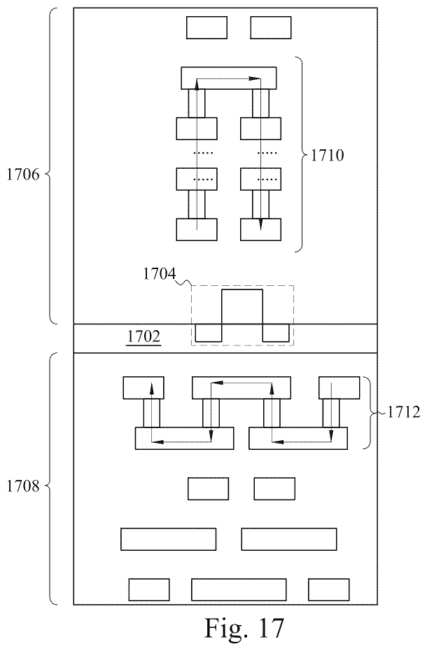

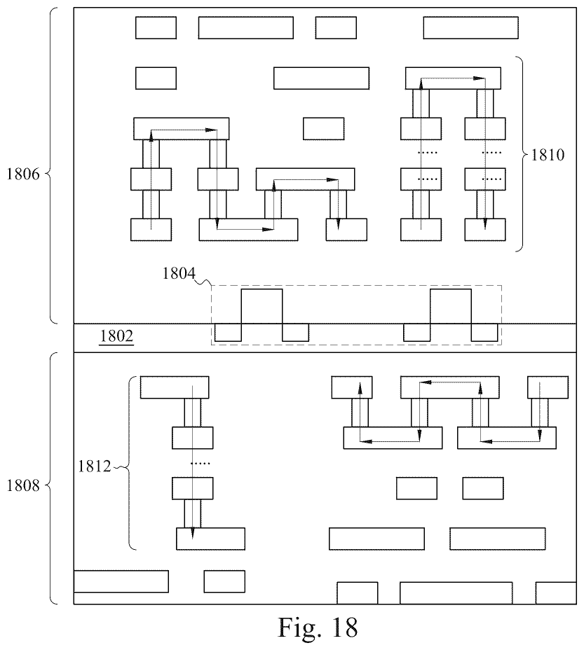

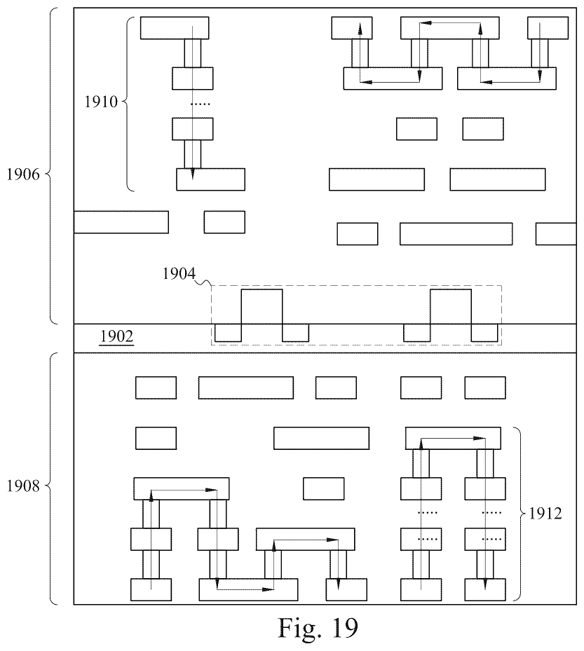

In the examples of FIGS. 6-8, the first memory array and the second memory array are of the same type. In other examples, the first memory array may be of a first type and the second memory array may be of a second type. For example, the first memory array may comprise a vertical serial memory array and the second memory array may comprise a horizontal serial memory array (see e.g., FIG. 12); the first memory array may comprise a horizontal serial memory array and the second memory array may comprise a vertical serial memory array (see e.g., FIG. 13); the first memory array may comprise a vertical serial memory array and the second memory array may comprise a vertical and horizontal serial memory array (see e.g., FIG. 14); the first memory array may comprise a vertical and serial memory array and the second memory array may comprise a vertical serial memory array (see e.g., FIG. 15); the first memory array may comprise a horizontal serial memory array and the second memory array may comprise a vertical and horizontal serial memory array (see e.g., FIG. 16); the first memory array may comprise a vertical and horizontal serial memory array and the second memory array may comprise a horizontal serial memory array (see e.g., FIG. 17); the first memory array may comprise a vertical and horizontal serial memory array and the second memory array may comprise a vertical serial memory array and a horizontal serial memory array (see e.g., FIG. 18); and the first memory array may comprise a vertical serial memory array and a horizontal serial memory array and the second memory array may comprise a vertical and horizontal serial memory array (see e.g., FIG. 19). Other combinations are also contemplated.

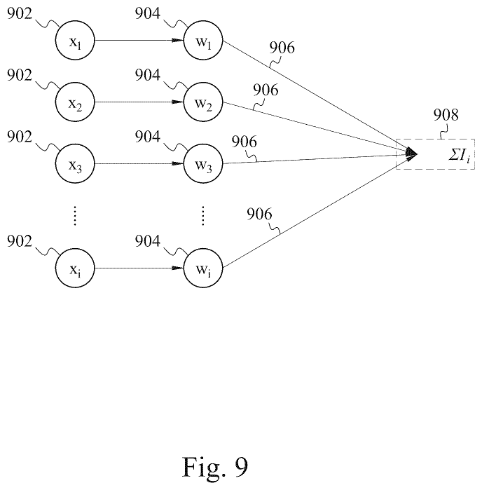

FIG. 9 depicts a schematic diagram illustrating an example artificial perception application of a CIS system that provides memory cells and neuromorphic computing capability. Depicted are a plurality of memory cells 902 from a serial memory array located in metal interconnection routing and a plurality of weights 904. The metal interconnection routing electrically connects the plurality of memory cells 902 to memory cell transistors. The content (e.g., state xᵢ) of each memory cell 902 is multiplied by an associated weight 904 (e.g., wᵢ). A series of outputs 906 is produced from the multiplication of the content (e.g., state xᵢ) of each memory cell 902 with its associated weight 904 (e.g., wᵢ). The series of outputs 906 are summed to produce a summed output 908, such as an artificial perception current ΣIᵢ.

The serial memory array is an N bit serial memory. The N bit serial memory has N+1 states including (N, 0), (N−1, 1), . . . (0,N). A serial memory array has anti-parallel state k bits and parallel state (N−k) bits. Each state of the serial memory array has a weight wᵢ, wherein wᵢ=k*R_high+(N−k)*R_low. Each signal xᵢ can current induce switch y bits of the memory array. Serial memory will become mᵢ=(k−y)*R_high+(N−k+y)*R_low. For MRAM resistance, R_{MTJ1}<R_{MTJ2}<R_{MTJ3} . . . <R_{MTJn}. For RRAM resistance, R_{RRAM1}<R_{RRAM2}<R_{RRAM3}. . . <R_{RRAMn}. Input signal current must start from small to large resistance of MRAM/RRAM. Multi N bit serial memory has an artificial perception current ΣIᵢ

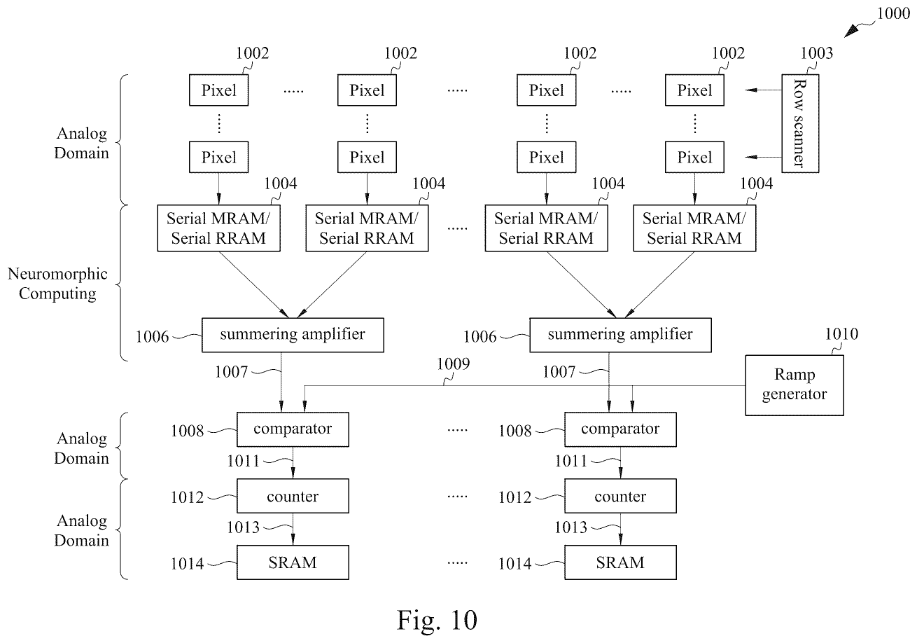

FIG. 10 depicts a block diagram illustrating an example application of a CIS system 1000 that provides memory cells and neuromorphic computing capability. The example CIS system 1000 includes a plurality of pixels 1002 (e.g., photosensitive pixel region 104), a plurality of memory cells 1004 in one or more serial memory arrays, and summing amplifiers 1006 (e.g., as part of ISP region 108). The plurality of memory cells 1004 and the summing amplifiers 1006 add a neuromorphic computing capability to the CIS system 1000. A row scanner 1003 may be used to select pixels 1002 for storage in memory cells 1004.

The example CIS system 1000 further includes a plurality of comparators 1008, a ramp generator 1010, a plurality of counters 1012, and a plurality of memory devices 1014 (e.g., SRAM). The comparator 1008 receives the output 1007 of the neuromorphic computing and a ramp signal 1009 from the ramp generator 1010, and outputs a comparison signal 1011 by comparing the received neuromorphic computing output 1007 and the ramp signal 1009. The counter 1012 is coupled to the comparator 1008 to receive the comparison signal 1011. The counter 1012 outputs a counting value 1013 according to the comparison signal. The counting value 1013 is then stored in the memory devices 1014. In an embodiment of the present disclosure, the counter 1012 may be a hybrid counter where the lower bits (e.g., least significant bits) and upper bit (e.g., most significant bits) are counted separately, thereby improving the counting speed and saving power consumption for the counter. In an embodiment of the present disclosure, the plurality of comparators 1008, ramp generator 1010, plurality of counters 1012, and plurality of memory devices 1014 may function as an analog to digital converter (ADC).

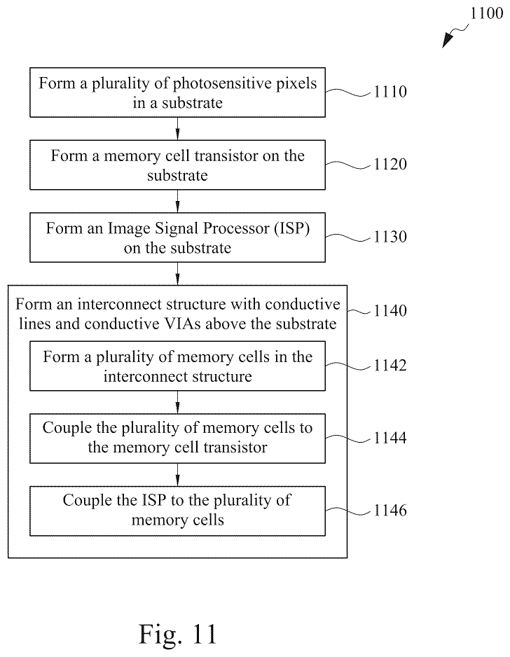

FIG. 11 is a flowchart of an example method for fabricating a CIS system with neuromorphic computing capability, according to some embodiments. Depicted operations can be performed in a different order or not performed depending on specific applications. It should be noted that method 1100 may not produce a complete semiconductor device. Accordingly, it is understood that additional processes can be provided before, during, and after method 1100, and that some other processes may only be briefly described herein.

It is understood that parts of the semiconductor device may be fabricated by typical semiconductor technology process flow, and thus some processes are only briefly described herein. Further, the exemplary semiconductor devices may include various other devices and features, such as other types of devices such as additional transistors, bipolar junction transistors, resistors, capacitors, inductors, diodes, fuses, and/or other logic devices, etc., but is simplified for a better understanding of concepts of the present disclosure. In some embodiments, the exemplary devices include a plurality of semiconductor devices (e.g., transistors), including PFETs, NFETs, etc., which may be interconnected. Moreover, it is noted that the operations of method 1100, including any descriptions given with reference to the Figures are merely exemplary and are not intended to be limiting beyond what is specifically recited in the claims that follow.

At block 1110, the example method 1100 includes forming a plurality of photosensitive pixels in a substrate. The photosensitive pixels may include a photosensitive detection area and a plurality of pixel transistors.

At block 1120, the example method 1100 includes forming a memory cell transistor on a substrate. The memory cell transistor is configured to pass content from the photosensitive pixels to associated memory cells.

At block 1130, the example method 1100 includes forming an Image Signal Processor (ISP) on a substrate. The ISP is configured to process content from the photosensitive pixels and content stored in the associated memory cells and provide a neuromorphic computing capability.

At block 1140, the example method 1100 includes forming an interconnect structure with conductive lines and conductive VIAs above the substrate. Forming the interconnect structure includes block 1142, block 1144, and block 1146.

At block 1142, the example method 1100 includes forming a plurality of serial memory cells in the interconnect structure. The memory cells may comprise MRAM memory cells, RRAM memory cells, or other suitable memory cells. The memory cells may comprise vertical serial memory cells, horizontal serial memory cells, vertical and horizontal serial memory cells, and/or various combinations.

At block 1144, the example method 1100 includes coupling the plurality of memory cells to the memory cell transistor; and At block 1146, the example method 1100 includes coupling the ISP to the plurality of memory cells, wherein the ISP is configured to provide a neuromorphic computing capability.

FIG. 12 depicts a substrate 1202 with memory cell transistors 1204 on the substrate, a first interconnect structure 1206 above the substrate and a second interconnect structure 1208 below the substrate. The first interconnect structure 1206 includes a first memory array 1210, and the second interconnect structure 1208 includes a second memory array 1212. The memory cell transistors 1204 are configured to provide data to the first memory array 1210 and the second memory array 1212. In this example, the first memory array 1210 comprises a vertical serial memory array and the second memory array 1212 comprises a horizontal serial memory array.

FIG. 13 depicts a substrate 1302 with memory cell transistors 1304 on the substrate, a first interconnect structure 1306 above the substrate and a second interconnect structure 1308 below the substrate. The first interconnect structure 1306 includes a first memory array 1310, and the second interconnect structure 1308 includes a second memory array 1312. The memory cell transistors 1304 are configured to provide data to the first memory array 1310 and the second memory array 1312. In this example, the first memory array 1310 comprises a horizontal serial memory array and the second memory array 1312 comprises a vertical serial memory array.

FIG. 14 depicts a substrate 1402 with memory cell transistors 1404 on the substrate, a first interconnect structure 1406 above the substrate and a second interconnect structure 1408 below the substrate. The first interconnect structure 1406 includes a first memory array 1410, and the second interconnect structure 1408 includes a second memory array 1412. The memory cell transistors 1404 are configured to provide data to the first memory array 1410 and the second memory array 1412. In this example, the first memory array 1410 comprises a vertical serial memory array and the second memory array 1412 comprises a vertical and horizontal serial memory array.

FIG. 15 depicts a substrate 1502 with memory cell transistors 1504 on the substrate, a first interconnect structure 1506 above the substrate and a second interconnect structure 1508 below the substrate. The first interconnect structure 1506 includes a first memory array 1510, and the second interconnect structure 1508 includes a second memory array 1512. The memory cell transistors 1504 are configured to provide data to the first memory array 1510 and the second memory array 1512. In this example, the first memory array 1510 comprises a vertical and horizontal serial memory array and the second memory array 1512 comprises a vertical serial memory array.

FIG. 16 depicts a substrate 1602 with memory cell transistors 1604 on the substrate, a first interconnect structure 1606 above the substrate and a second interconnect structure 808 below the substrate. The first interconnect structure 1606 includes a first memory array 1610, and the second interconnect structure 1608 includes a second memory array 1612. The memory cell transistors 1604 are configured to provide data to the first memory array 1610 and the second memory array 1612. In this example, the first memory array 1610 comprises a horizontal serial memory array and the second memory array 1612 comprises a vertical and horizontal serial memory array.

FIG. 17 depicts a substrate 1702 with memory cell transistors 1704 on the substrate, a first interconnect structure 1706 above the substrate and a second interconnect structure 1708 below the substrate. The first interconnect structure 1706 includes a first memory array 1710, and the second interconnect structure 1708 includes a second memory array 1712. The memory cell transistors 1704 are configured to provide data to the first memory array 1710 and the second memory array 1712. In this example, the first memory array 1710 comprises a vertical and horizontal serial memory array and the second memory array 1312 comprises a horizontal serial memory array.

FIG. 18 depicts a substrate 1802 with memory cell transistors 1804 on the substrate, a first interconnect structure 1806 above the substrate and a second interconnect structure 1808 below the substrate. The first interconnect structure 1806 includes a first memory array 1810, and the second interconnect structure 1808 includes a second memory array 1812. The memory cell transistors 1804 are configured to provide data to the first memory array 1810 and the second memory array 1812. In this example, the first memory array 1810 comprises a vertical and horizontal serial memory array and the second memory array 1812 comprises both a vertical serial memory array and a horizontal serial memory array.

FIG. 19 depicts a substrate 1902 with memory cell transistors 1904 on the substrate, a first interconnect structure 1906 above the substrate and a second interconnect structure 1908 below the substrate. The first interconnect structure 1906 includes a first memory array 1910, and the second interconnect structure 1908 includes a second memory array 1912. The memory cell transistors 1904 are configured to provide data to the first memory array 1910 and the second memory array 1912. In this example, the first memory array 1910 comprises both a vertical serial memory array and a horizontal serial memory array and the second memory array 1912 comprises a vertical and horizontal serial memory array.

In various embodiments, various types of semiconductor structures may be formed for a CIS device with neuromorphic capabilities. In various embodiments, a CIS device with neuromorphic capabilities may comprise a 3DIC (three dimensional integrated circuit) bond, SoIC (small outline integrated circuit) bond, InFO (integrated Fan-Out), CoWoS (Chip-on-wafer-on-substrate), die on die, small die on big die, and other configurations.

In the foregoing examples, the illustrated transistors were planar transistors, such as an FET or MOSFET. In other examples, non-planar transistors, such as a FinFET device, a GAA (gate all around) device, a 2D material device, a vertical device, or a BEOL device may be used.

In some aspects, the techniques described herein relate to a semiconductor structure, including: a plurality of photosensitive pixels in a substrate; an interconnect structure over a first side of the substrate; a memory region including a plurality of memory cells formed in the interconnect structure, wherein the interconnect structure is configured to couple photosensitive pixels to the plurality of memory cells; and an Image Signal Processor (ISP) coupled to the plurality of memory cells via the interconnect structure, wherein the ISP is configured to provide a neuromorphic computing capability.

In some aspects, the techniques described herein relate to a semiconductor structure, wherein the plurality of memory cells include a magnetoresistive random access memory (MRAM) device.

In some aspects, the techniques described herein relate to a semiconductor structure, wherein the plurality of memory cells include a resistive random access memory (RRAM) device.

In some aspects, the techniques described herein relate to a semiconductor structure, wherein the plurality of memory cells include a plurality of serial memory cells that are configured to pass content in series from one memory cell to another.

In some aspects, the techniques described herein relate to a semiconductor structure, wherein the interconnect structure includes a plurality of interconnect layers and wherein the plurality of memory cells include a plurality of vertical serial memory cells that are configured to pass content in series from a first memory cell in a first interconnect layer of the interconnect structure to a second memory cell in a second interconnect layer of the interconnect structure that is above or below the first interconnect layer.

In some aspects, the techniques described herein relate to a semiconductor structure, wherein the interconnect structure includes a plurality of interconnect layers and wherein the plurality of memory cells include a plurality of horizontal serial memory cells that are configured to pass content in series from a first memory cell at a first level in the interconnect structure to a second memory cell at the first level in the interconnect structure.

In some aspects, the techniques described herein relate to a semiconductor structure, wherein the interconnect structure includes a plurality of interconnect layers and wherein the plurality of memory cells include a plurality of horizontal serial memory cells that are configured to pass content in series from a first memory cell in a first level in the interconnect structure to a second memory cell in the first level in the interconnect structure and a plurality of vertical serial memory cells that are configured to pass content in series from a third memory cell in a second level in the interconnect structure to a fourth memory cell in a third level in the interconnect structure that is above or below the second level.

In some aspects, the techniques described herein relate to a semiconductor structure, further including: a second interconnect structure below a second side of the substrate; a second plurality of memory cells formed in the second interconnect structure, wherein the second interconnect structure is configured to couple photosensitive pixels to the second plurality of memory cells; and the Image Signal Processor (ISP) is coupled to the second plurality of memory cells via the second interconnect structure to provide the neuromorphic computing capability.

In some aspects, the techniques described herein relate to a method including: forming a plurality of photosensitive pixels in a substrate; forming a memory cell transistor on a substrate; forming an Image Signal Processor (ISP) on a substrate; and forming an interconnect structure with conductive lines and conductive VIAs above a substrate, wherein forming the interconnect structure includes: forming a plurality of memory cells in the interconnect structure; coupling the plurality of memory cells to the memory cell transistor; and coupling the ISP to the plurality of memory cells, wherein the ISP is configured to provide a neuromorphic computing capability.

In some aspects, the techniques described herein relate to a method, wherein forming the plurality of memory cells includes forming a magnetoresistive random access memory (MRAM) device.

In some aspects, the techniques described herein relate to a method, wherein forming the plurality of memory cells includes forming a resistive random access memory (RRAM) device.

In some aspects, the techniques described herein relate to a method, wherein forming the plurality of memory cells includes forming a plurality of serial memory cells that are configured to pass content in series from one memory cell to another.

In some aspects, the techniques described herein relate to a method, wherein forming the plurality of memory cells includes forming a plurality of vertical serial memory cells that are configured to pass content in series from a first memory cell in a first level in the interconnect structure to a second memory cell in a second level in the interconnect structure that is above or below the first level.

In some aspects, the techniques described herein relate to a method, wherein forming the plurality of memory cells includes forming a plurality of horizontal serial memory cells that are configured to pass content in series from a first memory cell in a first level in the interconnect structure to a second memory cell in the first level in the interconnect structure.

In some aspects, the techniques described herein relate to a semiconductor structure, including: a plurality of photosensitive pixels including a plurality of pixel transistors and a photosensitive detection area; a interconnect structure over the photosensitive detection area; a memory region including a memory transistor disposed on a substrate and a plurality of memory cells formed in the interconnect structure, wherein the interconnect structure is configured to couple photosensitive pixels to the plurality of memory cells via the memory transistor; and an Image Signal Processor (ISP) coupled to the plurality of memory cells, wherein the ISP is configured to provide a neuromorphic computing capability.

In some aspects, the techniques described herein relate to a semiconductor structure, wherein: the memory region is on a first wafer; and the ISP is on a second wafer that is bonded to the first wafer.

In some aspects, the techniques described herein relate to a semiconductor structure, wherein: the second wafer includes a second interconnect structure; and the second interconnect structure is bonded to the interconnect structure.

In some aspects, the techniques described herein relate to a semiconductor structure, wherein: the second wafer includes a second interconnect structure; and the second interconnect structure is bonded to a side of the substrate opposite to a second side of the substrate above which the interconnect structure is disposed.

In some aspects, the techniques described herein relate to a semiconductor structure, further including: a first wafer and a second wafer; and wherein the plurality of pixel transistors, the photosensitive detection area, the memory transistor, and the interconnect structure are disposed on the first wafer; wherein the ISP is disposed on the second wafer.

In some aspects, the techniques described herein relate to a semiconductor structure, further including: a first wafer, a second wafer, and a third wafer; wherein the photosensitive detection area is disposed on the first wafer; and wherein the plurality of pixel transistors, the memory transistor, and the interconnect structure are disposed on the second wafer; wherein the ISP is disposed on the third wafer.

In some aspects, the techniques described herein relate to a semiconductor structure, wherein: the plurality of photosensitive pixels are disposed on a first semiconductor wafer, the memory region includes a memory transistor disposed on the first semiconductor wafer, and the ISP is disposed on a semiconductor second wafer.

In some aspects, the techniques described herein relate to a semiconductor structure, wherein: the photosensitive pixels include a plurality of pixel transistors and a photosensitive detection area, the photosensitive detection area is disposed on a first semiconductor wafer, the plurality of pixel transistors is disposed on a second semiconductor wafer, the memory region includes a memory transistor disposed on the second semiconductor wafer, and the ISP is disposed on a third semiconductor wafer.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor structure, comprising:
a plurality of photosensitive pixels in a substrate;
an interconnect structure over a first side of the substrate;
a memory region comprising a plurality of memory cells formed in the interconnect structure, wherein the interconnect structure is configured to couple photosensitive pixels to the plurality of memory cells; and
an Image Signal Processor (ISP) coupled to the plurality of memory cells via the interconnect structure, wherein the ISP is configured to provide a neuromorphic computing capability.

2. The semiconductor structure of claim 1, wherein the plurality of memory cells comprise a magnetoresistive random access memory (MRAM) device.

3. The semiconductor structure of claim 1, wherein the plurality of memory cells comprise a resistive random access memory (RRAM) device.

4. The semiconductor structure of claim 1, wherein the plurality of memory cells comprise a plurality of serial memory cells that are configured to pass content in series from one memory cell to another.

5. The semiconductor structure of claim 1, wherein the interconnect structure comprises a plurality of interconnect layers and wherein the plurality of memory cells comprise a plurality of vertical serial memory cells that are configured to pass content in series from a first memory cell in a first interconnect layer of the interconnect structure to a second memory cell in a second interconnect layer of the interconnect structure that is above or below the first interconnect layer.

6. The semiconductor structure of claim 1, wherein the interconnect structure comprises a plurality of interconnect layers and wherein the plurality of memory cells comprise a plurality of horizontal serial memory cells that are configured to pass content in series from a first memory cell at a first level in the interconnect structure to a second memory cell at the first level in the interconnect structure.

7. The semiconductor structure of claim 1, wherein the interconnect structure comprises a plurality of interconnect layers and wherein the plurality of memory cells comprise a plurality of horizontal serial memory cells that are configured to pass content in series from a first memory cell in a first level in the interconnect structure to a second memory cell in the first level in the interconnect structure and a plurality of vertical serial memory cells that are configured to pass content in series from a third memory cell in a second level in the interconnect structure to a fourth memory cell in a third level in the interconnect structure that is above or below the second level.

8. The semiconductor structure of claim 1, further comprising:
a second interconnect structure below a second side of the substrate;
a second plurality of memory cells formed in the second interconnect structure, wherein the second interconnect structure is configured to couple photosensitive pixels to the second plurality of memory cells; and
the Image Signal Processor (ISP) is coupled to the second plurality of memory cells via the second interconnect structure to provide the neuromorphic computing capability.

9. A method comprising:
forming a plurality of photosensitive pixels in a substrate;
forming a memory cell transistor on a substrate;
forming an Image Signal Processor (ISP) on a substrate; and
forming an interconnect structure with conductive lines and conductive VIAs above a substrate, wherein forming the interconnect structure comprises:
forming a plurality of memory cells in the interconnect structure;
coupling the plurality of memory cells to the memory cell transistor; and
coupling the ISP to the plurality of memory cells, wherein the ISP is configured to provide a neuromorphic computing capability.

10. The method of claim 9, wherein forming the plurality of memory cells comprises forming a magnetoresistive random access memory (MRAM) device.

11. The method of claim 9, wherein forming the plurality of memory cells comprises forming a resistive random access memory (RRAM) device.

12. The method of claim 9, wherein forming the plurality of memory cells comprises forming a plurality of serial memory cells that are configured to pass content in series from one memory cell to another.

13. The method of claim 9, wherein forming the plurality of memory cells comprises forming a plurality of vertical serial memory cells that are configured to pass content in series from a first memory cell in a first level in the interconnect structure to a second memory cell in a second level in the interconnect structure that is above or below the first level.

14. The method of claim 9, wherein forming the plurality of memory cells comprises forming a plurality of horizontal serial memory cells that are configured to pass content in series from a first memory cell in a first level in the interconnect structure to a second memory cell in the first level in the interconnect structure.

15. A semiconductor structure, comprising:
a plurality of photosensitive pixels comprising a plurality of pixel transistors and a photosensitive detection area;
a interconnect structure over the photosensitive detection area;
a memory region comprising a memory transistor disposed on a substrate and a plurality of memory cells formed in the interconnect structure, wherein the interconnect structure is configured to couple photosensitive pixels to the plurality of memory cells via the memory transistor; and
an Image Signal Processor (ISP) coupled to the plurality of memory cells, wherein the ISP is configured to provide a neuromorphic computing capability.

16. The semiconductor structure of claim 15, wherein:
the memory region is on a first wafer; and
the ISP is on a second wafer that is bonded to the first wafer.

17. The semiconductor structure of claim 16, wherein:
the second wafer comprises a second interconnect structure; and
the second interconnect structure is bonded to the interconnect structure.

18. The semiconductor structure of claim 16, wherein:
the second wafer comprises a second interconnect structure; and
the second interconnect structure is bonded to a side of the substrate opposite to a second side of the substrate above which the interconnect structure is disposed.

19. The semiconductor structure of claim 15, further comprising:
a first wafer and a second wafer; and
wherein the plurality of pixel transistors, the photosensitive detection area, the memory transistor, and the interconnect structure are disposed on the first wafer;
wherein the ISP is disposed on the second wafer.

20. The semiconductor structure of claim 15, further comprising:
a first wafer, a second wafer, and a third wafer;
wherein the photosensitive detection area is disposed on the first wafer; and
wherein the plurality of pixel transistors, the memory transistor, and the interconnect structure are disposed on the second wafer;
wherein the ISP is disposed on the third wafer.
